(19) United States
(12) Patent Application Publication
(10) Pub. No.: US 2017/0237437 A1
(43) Pub. Date: Aug. 17, 2017

(54) Small Area Native Level Shifter

(71) Applicant: Avego Technologies General IP (Singapore) Pte. Ltd

(72) Inventor: Jeffrey CHIN, Singapore (SG)

(73) Assignee: Avego Technologies General IP (Singapore) Pte. Ltd

(21) Appl. No.: 15/043,156

(22) Filed: Feb. 12, 2016

(51) Int. Cl. H03K 19/0185

(52) U.S. Cl. CPC H03K 19/018521

(57) ABSTRACT

Structure for a level shifter circuit is provided that includes a native transistor. The level shifter circuit includes transistors that are configured as an inverter and the native transistor configured to remain on or in a subthreshold region. The level shifter circuit is configured to receive a first input signal that ranges between ground and a first voltage and output an output signal that ranges from ground to a second voltage greater than the first voltage. The structure reduces an area required by the level shifter circuit and consumes a low amount of standby current.

### BACKGROUND

Field

Embodiments described herein generally relate to a level shifter that uses a native transistor to reduce a structural area and standby current leakage in the level shifter.

Background

Typical powered devices include components that use different voltages, which may cause incompatibility issues when these components communicate with each other. To resolve these issues, powered devices may include level shifters to provide an interface between the components that use different voltages. Level shifters are commonly used by low powered devices to convert a voltage standard used by one component to a different voltage standard used by another component. Some commonly used level shifters require a substantial amount of area within a powered device and consume excessive amounts of current when in standby.

### BRIEF DESCRIPTION OF THE DRAWINGS/FIGURES

The accompanying drawings, which are incorporated herein and form part of the specification, illustrate the present disclosure and, together with the description, further serve to explain the principles of the disclosure and to enable a person skilled in the relevant art(s) to make and use the disclosure.

FIGS. 1A-1C illustrate conventional level shifter circuits.

FIG. 2A illustrates a detailed diagram of a level shifter circuit, in accordance with an embodiment of the present disclosure.

FIG. 2B illustrates a timing diagram of various signals within a level shifter circuit according to an exemplary embodiment of the present disclosure

FIG. 3A illustrates another detailed diagram of a level shifter circuit, in accordance with an embodiment of the present disclosure.

FIG. 3B illustrates another detailed diagram of a level shifter circuit, in accordance with an embodiment of the present disclosure.

FIG. 4 illustrates a level shifter circuit having a reset circuit, in accordance with an embodiment of the present disclosure.

The present disclosure will now be described with reference to the accompanying drawings. In the drawings, generally, like reference numbers indicate identical or functionally similar elements. Additionally, generally, the left-most digit(s) of a reference number identifies the drawing in which the reference number first appears.

### DETAILED DESCRIPTION

### Overview

A level shifter circuit is provided that utilizes a native transistor to provide a reduced area and maintain a low current leakage.

### Detailed Discussion

The following Detailed Description of the present disclosure refers to the accompanying drawings that illustrate exemplary embodiments consistent with this disclosure. The exemplary embodiments will so fully reveal the general nature of the disclosure that others can, by applying knowledge of those skilled in relevant art(s), readily modify and/or adapt for various applications such exemplary embodiments, without undue experimentation, without departing from the spirit and scope of the disclosure. Therefore, such adaptations and modifications are intended to be within the meaning and plurality of equivalents of the exemplary embodiments based upon the teaching and guidance presented herein. It is to be understood that the phraseology or terminology herein is for the purpose of description and not of limitation, such that the terminology or phraseology of the present specification is to be interpreted by those skilled in relevant art(s) in light of the teachings herein. Therefore, the detailed description is not meant to limit the present disclosure.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

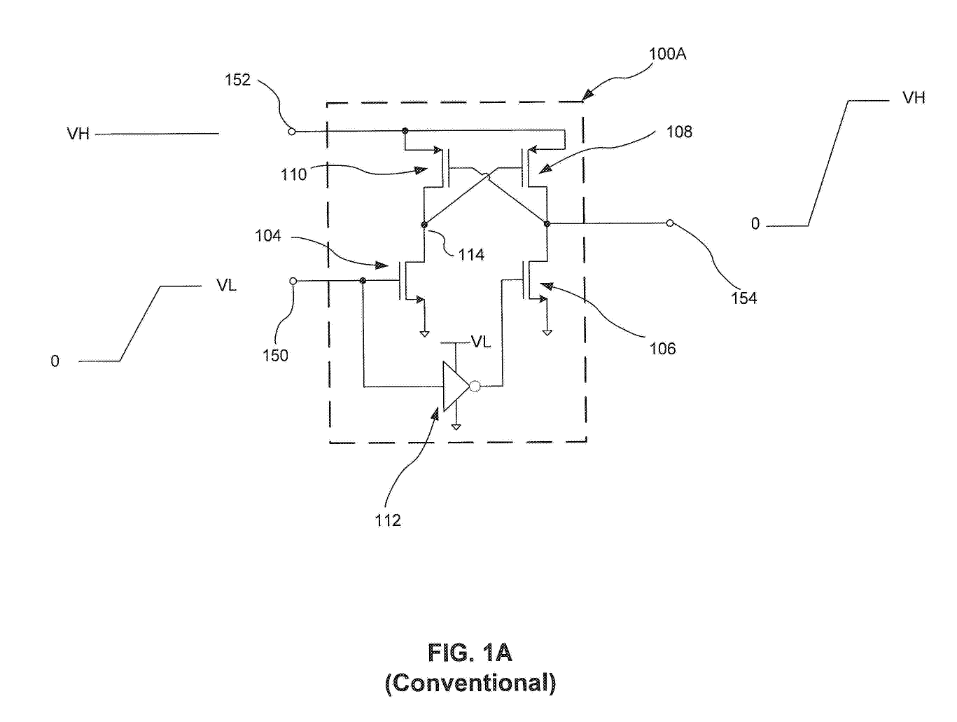

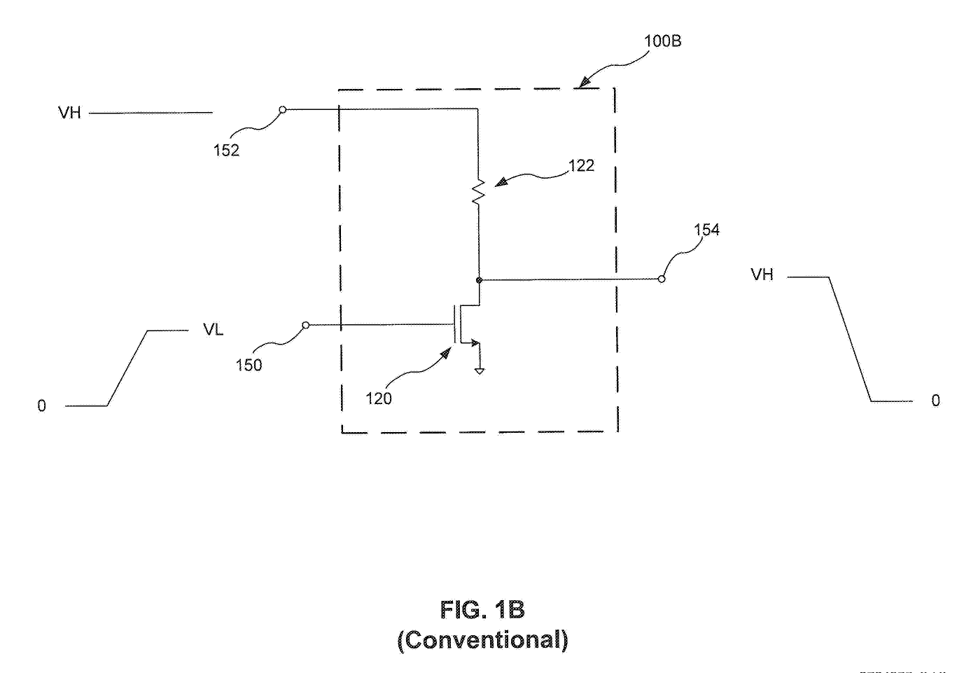

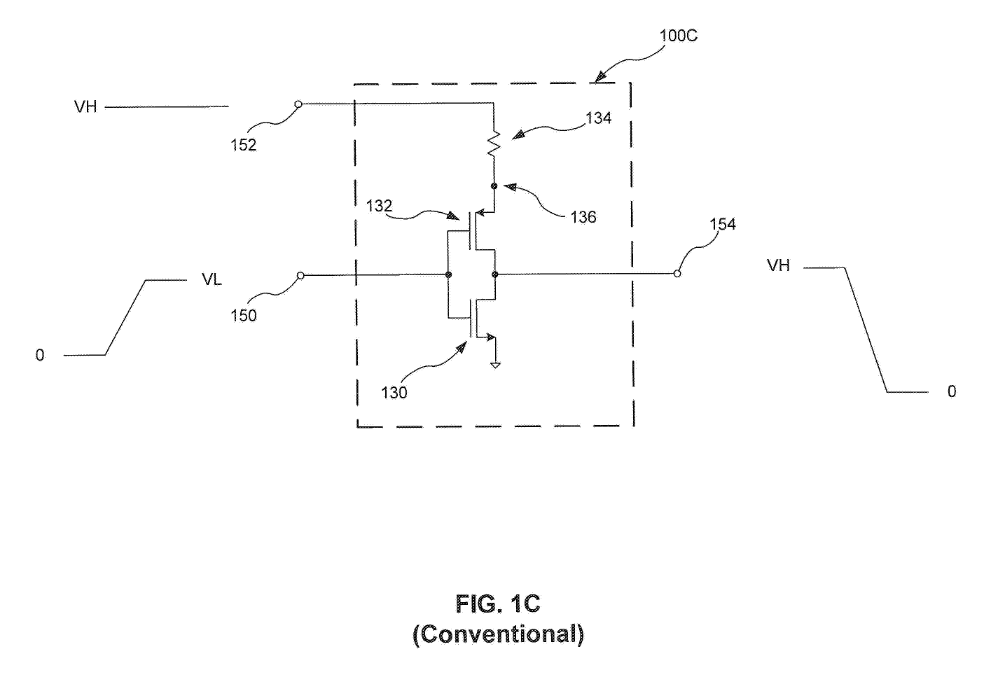

FIGS. 1A-1C illustrate conventional level shifter circuits 100A-100C. Each of the level shifter circuits 100A-100C includes an input terminal 150, a high voltage terminal 152, and an output terminal 154. The input terminal 150 receives an input signal which ranges between a “low” logic (or “0”) and a “high” logic (or “1”). The high logic of the input signal is typically referred to as a low voltage VL, and may be 1.8 volts, to provide an example. The high voltage terminal 152 receives a high voltage VH, which is a voltage greater than the low voltage VL. The high voltage VH may be 3.6 volts, to provide an example.

As shown by FIG. 1A, the level shifter circuit 100A is a cross-coupled level shifter. The level shifter circuit 100A includes N-type field-effect transistors (NFETs) 104 and 106, P-type field-effect transistors (PFETs) 108 and 110, and an inverter 112. The NFET 104 includes a gate connected to an input terminal 150, a source connected to ground, and a drain connected to a drain of the PFET 110 at a node 114. The NFET 104 is configured to pull down a voltage at the node 114 when the input signal on the input terminal 150 is driven to a logic one. In other words, a logic one on the input terminal 150 causes the NFET 104 to conduct and therefore node 114 is pulled to ground since the source of the NFET 104 is grounded.

The inverter 112 includes an input connected to the input terminal 150 and an output connected to a gate of the NFET 106. The inverter 112 is configured to invert the logic of the input signal. As an example, the output of the inverter 112 is a logic one (i.e., the low voltage VL) when the input signal is a logic zero.

The NFET 106 includes the gate connected to the output of the inverter 112, a source connected to ground, and a drain connected to a drain of the PFET 108. The NFET 106 is configured to pull down the output signal on the output terminal 154 when the input signal received at input terminal 150 is a logic zero. For example, the output signal is pulled down to 0 volts when the input signal on the input terminal 150 is a logic zero since the inverter 112 inverters the logic zero to logic one, so that the NFET 106 conducts.

The PFET 108 includes a gate connected to the node 114, a source connected to the high voltage terminal 152, and the drain connected to the drain of the NFET 106. The PFET 108 is configured to pull up the output signal on the output terminal 154 to the high voltage VH when the input signal on input terminal 150 is a logic one. More specifically, as described above, a logic one received at the input terminal 150 causes the NFET 104 to conduct so that the node 114 is grounded, which is also connected to the gate of the PFET 108. Accordingly, the PFET 108 conducts with a grounded gate so that the high voltage VH is applied to the output terminal 154. The NFET 106 is cutoff with a logic one input, so that the high voltage VII holds at the output terminal 154.

The PFET 110 includes a gate connected to the output terminal 154, a source connected to the high voltage terminal 152, and the drain connected to the drain of the NFET 104 at the node 114. The PFET 110 is configured to pull up the voltage at the node 114 to the high voltage VII when the input signal on the input terminal 150 is driven to a logic zero. More specifically, a logic zero on the input terminal 150 causes the NFET 106 to conduct, after the input signal has been inverted by the inverter 112, so as to pull down the gate of the PFET 110 to ground, and thereby the drain of the PFET 110 is pulled up to the high voltage VH.

While the level shifter circuit 100A is widely used by low power devices, there exists common and known issues. For example, the overall area required by the level shifter circuit 100A is relatively large because proper operation requires (a) the NFETs 104 and 106 to be larger than the PFETs 108 and 110, and (b) a minimum of six transistors (e.g., the NFETs 104 and 106, the PFETs 108 and 110, and two transistors for the inverter 112).

Additionally, when in operation, the output of the inverter 112 can go to an uncontrolled voltage of either the low voltage VL or ground when the input signal on the input terminal 150 is lost, or becomes disconnected or floats, and the output can remain at the uncontrolled voltage even if the input signal goes to 0 volts.

FIG. 1B illustrates another conventional level shifter circuit 100B. The level shifter circuit 100B includes an NFET 120 and a resistor 122. The NFET 120 includes a gate that connects to the input terminal 150, a drain that connects to the output terminal 154, and a source connected to ground. As shown, the resistor 122 connects between the high voltage terminal 152 and the drain of the output terminal 154. The resistor 134 can include a resistor and/or a combination of diode strings.

The NFET 120 is configured to pull down an output signal on the output terminal 154 to ground when the input signal on an input terminal 150 is driven to a logic one. The output signal is 0 volts when the input signal is driven to the low voltage VL, to provide an example. Alternatively, when the input signal is a logic zero, then the NFET 120 is cutoff (e.g. not conducting), so the output terminal 154 remains at the high voltage VH.

In comparison with the level shifter circuit 100A, the level shifter circuit 100B is much simpler by only requiring the two components (i.e., the NFET 120 and the resistor 122). However, the resistor 122 still requires a significant amount of area on a circuit, and the level shifter circuit 100B consumes current when the input signal is at a logic one. In other words, the level shifter circuit 100B has a shoot through current while the NFET 120 is turned on. Further, the output signal of level shifter circuit 100B is well defined when the input signal is lost, becomes 0 volts, or floats.

FIG. 1C illustrates another conventional level shifter circuit 100C. The level shifter circuit 100C includes an NFET 130, a PFET 132, and a resistor 134. As will be described in more detail, the NFET 130 and the PFET 132 are configured as an inverter. The resistor 134 is connected between the high voltage terminal 152 and the source of the PFET 132. The resistor 134 can include a resistor and/or a combination of diode strings.

The NFET 130 includes a gate connected to the input terminal 150, a drain that connects to the output terminal 154, and a source connected to ground. The NFET 130 is configured to pull down an output signal on the output terminal 154 to ground when the input signal on an input terminal 150 is driven to a logic one. For example, the output signal is 0 volts when the input signal is driven to the low voltage VL.

The PFET 132 includes a gate connected to the input terminal 150, a drain connected to the output terminal 154, and a source connected to a terminal of the resistor 134. For convenience, the connection between the source of the PFET 132 and terminal of the resistor 134 is referred to as a node 136. The PFET 132 pulls up the output signal to an intermediate voltage at the node 136 when the input signal is driven to a logic zero (e.g., 0 volts). As an example, the voltage of the output signal is 3.6 volts (e.g. logic high) when the input signal is 0 volts (e.g. logic low). This occurs because the PFET 132 conducts when a logic zero is applied to its gate.

Similar to the level shifter circuit 100B, the level shifter circuit 100C allows the output signal to be at a known state even when the input signal on the input terminal 150 is lost, becomes disconnected, or floats. Further, the level shifter circuit 100B includes the PFET 132 to prevent the shoot-through current when the NFET 130 is turned on.

In comparison to the level shifter circuit 100A, the level shifter circuit 100C requires fewer components and requires less area on a device. However, the level shifter circuit 100C does not work well when the low voltage VL is significantly less than the high voltage VH.

### Exemplary Embodiment

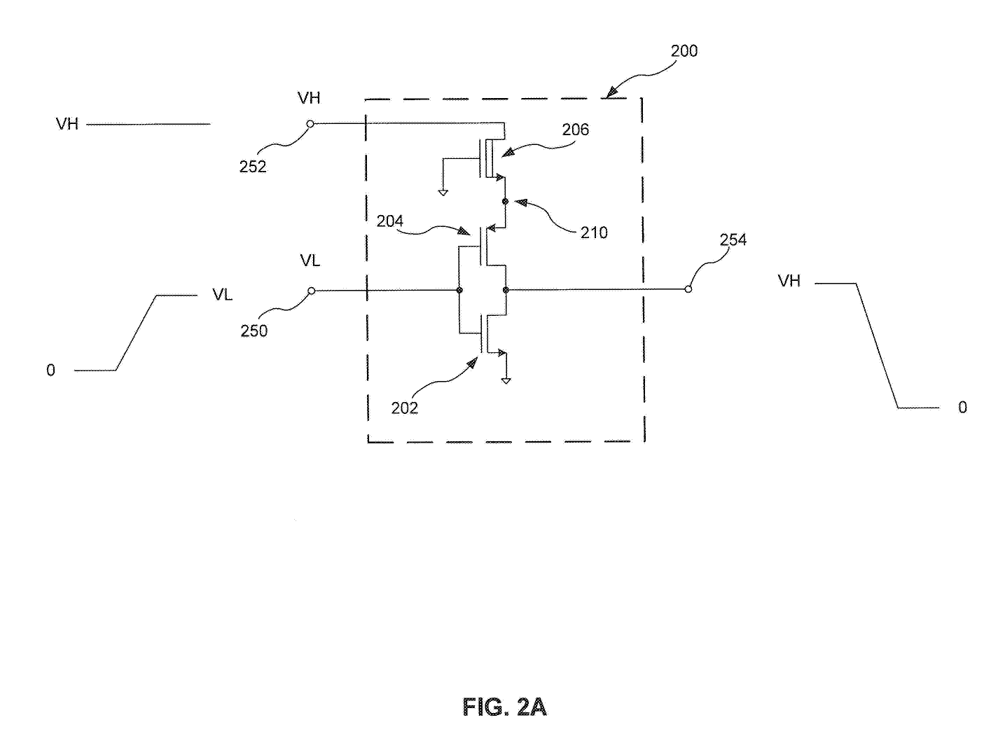

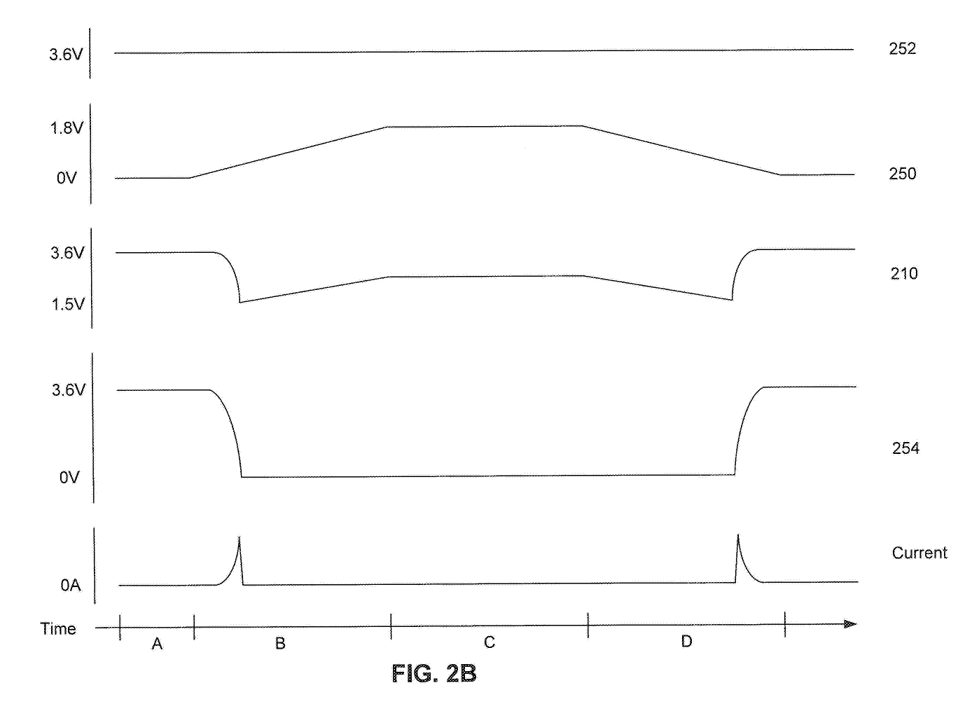

FIG. 2A illustrates a level shifter circuit 200, in accordance with an embodiment of the present disclosure.

The level shifter circuit 200 can be incorporated in any multi-voltage circuit that uses more than one voltage standard for functionality. For example, the level shifter circuit 200 may be included in an electronic device such as a computer, a laptop, a mobile phone, a tablet, an electronic reader, etc. that requires the use of a level shifter circuit utilizing a small amount of area, and a level shifter circuit that consumes a low amount of standby current.

As illustrated by FIG. 2A, the level shifter circuit 200 includes a first input terminal 250, a second input terminal 252, and an output terminal 254. The level shifter circuit 200 is configured to receive a first input signal on the first input terminal 250. A voltage of the first input signal is between a predetermined voltage range. As an example, a voltage of the first input signal can be between approximately a low of 0 volts representing a logic “low” (or “0”), and a high of 1.8 volts representing a logic “high” (or “1”). The high voltage of the first input signal may be referred to as a low voltage signal VL, even though it is a logic high. The level shifter circuit 200 is further configured to receive a second input signal on the second input terminal 252. A voltage of the second input signal is a predetermined voltage such as 3.6 volts, to provide an example. The voltage of the second input signal may be referred to as the high voltage VH. The level shifter circuit 200 is also configured to output an output signal on the output terminal 254. The output signal is an inverted form of the first input signal having a voltage that ranges from a low of the first input signal to the high voltage VH. As an example, the voltage of the output signal may range between a low of 0 volts representing a logic low (e.g. “0”) and a high of 3.6 volts representing a logic high (e.g. “1”), where the output signal substantially tracks an inverse of the first input signal from a high of 1.8 volts to 0 volts.

As will be understood by those skilled in the arts, and as will be described below in regards to other embodiments, the level shifter circuit 200 is not limited to two inputs and/or one output signal and can receive additional input signals and output additional output signals.

As shown by FIG. 2A, the level shifter circuit 200 includes an NFET 202, a PFET 204, and a native NFET 206. As will be described in more detail, the NFET 202 and the PFET 204 are configured as an inverter.

The NFET 202 includes a gate that connects to the first input terminal 250, a drain that connects to the output terminal 254, and a source connected to ground. The NFET 202 is configured to pull down the output signal on the output terminal 254 to ground when the first input signal on the first input terminal 250 is driven to a low voltage VL. The low voltage VL can be 1.8 volts, for example, and is a logic “high” that is sufficient to turn on NFET 202 and drive the output signal to ground. The output signal is 0 volts when the first input signal is driven to 1.8 volts, to provide an example.

As shown by FIG. 2A, the PFET 204 includes a gate connected to the first input terminal 250, a drain connected to the output terminal 254, and a source connected to a source of the native NFET 206. For convenience, the connection between the sources of the PFET 204 and the native NFET 206 is referred to as an intermediate node 210. The PFET 204 is configured to pull up the output signal to an intermediate voltage at the intermediate node 210 when the first input signal is driven to a low voltage of the first input signal. As an example, the voltage of the output signal is 3.6 volts (e.g. logic high) when the input signal is 0 volts (e.g. logic low).

Prior to describing the native NFET 206, a brief discussion about some of the differences and similarities between native transistors and typical transistors is provided. NFETs (such as NFET 202) and PFETs (such as 204) are distinct from native transistors (such as native NFET 206) as will be understood by those skilled in arts. Namely, NFETs are doped n-type so as to produce a channel with excess electrons under proper bias conditions and PFETs are doped p-type so as to produce a channel with excess holes under proper bias conditions. Further, both NFETs and PFETs have an inherent threshold voltage Vth that must be overcome, to form their respective channels for current to conduct and the transistors to be “on.” Whereas, native FETS are somewhere between enhancement mode and depletion mode transistors, have a thin N-channel layer for NFETs (or P-channel layer for PFETs) between the source and drain, and have a threshold voltage Vth of about 0V. Accordingly, native FETs are nominally “on” with a gate voltage of 0V, unless a bias voltage is applied to turn them “off.” For example, a negative gate voltage relative to the source voltage can be applied to turn native FETs off.

When a transistor (such as NFET 202, PFET 204, or native NFET 206) is “off,” an operation of the transistor generally implies that no current is flowing. However, this is not entirely true because a small amount of current may flow even when the threshold voltage Vth has not been surpassed. For example, even though an NFET device is generally cutoff when Vgs<Vth, a small amount of drain current may still flow when a gate to source voltage Vgs of the NFET is smaller than, but close to Vth. During this operation of the transistor, the transistor is said to operate in the subthreshold region or subthreshold conduction.

As shown by FIG. 2A, the native NFET 206 includes a gate connected to ground. Accordingly, the native NFET 206 is biased to never turn “off” and always operates in either an “on” state or a subthreshold region, e.g. slightly below the threshold voltage. Because it never turns “off”, the native NFET 206 provides a small drain to source leakage current. The native NFET 206 further includes a drain connected to the second input terminal 252, and the source is connected to the source of the PFET 204 at the intermediate node 210.

In comparison with the conventional logical shifter circuits 100A-100C, the level shifter circuit 200 circuit requires a significantly reduced amount of area in a device so as to provide as much as 1700 times area savings. The level shifter circuit 200 also significantly reduces an amount of leakage current when the first input signal is at a low voltage or a high voltage. Further, the level shifter circuit 200 maintains a well-defined output signal when the first input signal is at 0 volts or lost.

The above-described arrangement of the NFET 202, the PFET 204, and the native NFET 206 allows a designer of the level shifter circuit 200 to determine a voltage threshold Vth based on the width/length ratio of the native NFET 206 and/or the NFET 202 and the PFET 204 selected during a design of the level shifter circuit 200. The level shifter circuit 200 also allows a designer to use a low voltage VL that is significantly less than a high voltage VH in a device.

### Operation of the Level Shifter

An operation of the level shifter circuit 200 will now be discussed in reference to the waveforms of FIG. 2B. For simplicity in describing the different states, the time line is broken up into time ranges A-D.

During time range A, the first input terminal 250 has received the lowest voltage (e.g. “0” volts) of the first input signal for a predetermined amount of time. Accordingly, the NFET 202 is off, the PFET 204 is on, and the native NFET 206 is in deep subthreshold region but still conducting. In this configuration, the output signal at the output terminal 254 is substantially equal to the second input signal (e.g., 3.6 volts), and the intermediate voltage at the intermediate node 210 is substantially equal to the second input signal (e.g., 3.6 volts). Because the voltage of the output signal is substantially equal to the intermediate voltage, the PFET 204 conducts little to no current causing little to no current leakage, and there is no shoot through current from 3.6 volts to ground since the NFET 202 is off, as shown by FIG. 2B.

During time range B, the first input signal on the first input terminal 250 transitions from the lowest voltage of the first input signal (e.g., 0 volts) to the highest voltage of the first input signal (e.g., 1.8 volts). When the first input signal reaches close to the threshold voltage Vth (e.g., 0.4 volts), the NFET 202 begins to turn on which causes the output signal to be pulled down and creates a voltage difference Vds between the drain and the source of the PFET 204. The voltage difference Vds causes the PFET 204 to conduct and the intermediate voltage at intermediate node 210 to likewise be pulled down. The PFET 204 conducts until the first input signal reaches a cut off voltage of the PFET 204. At this point, the native NFET 206 operates in a near subthreshold region and the PFET 204 continues to weakly conduct because of the voltage difference Vds of the PFET 204. The intermediate voltage begins to increase similar to the first input signal and eventually settles between the highest voltage of the first input signal and second input signal (e.g., 2.5 volts), and the output voltage at output terminal 254 is pulled down to substantially 0 volts.

During time range C, the first input signal at the first input terminal 250 has been at the highest voltage for a predetermined amount of time. At this time, the NFET 202 is on, the PFET 204 is off, and the native NFET 206 is operating in the near subthreshold region. In this configuration, the PFET 204 weakly conducts because the voltage difference between the intermediate voltage at intermediate node 210 and the threshold voltage Vth is greater than the highest voltage of the first input signal. The weak conduction of the PFET 204 causes the intermediate voltage at the intermediate node 210 to remain between the second input signal and the highest voltage of the first input signal (e.g., 2.5 volts), and the output voltage to remain at substantially 0 volts.

During time range D, the first input signal transitions from the highest voltage of the first input signal (e.g., 1.8 volts) to the lowest voltage of the first input signal (e.g., 0 volts). The coupling of the gate and the drain voltage (Vgd) of the NFET 202 causes the intermediate voltage at node 210 to also decrease until the first input signal reaches the threshold voltage Vth. At this point, the NFET 202 turns off, the PFET 204 begins to conduct more, and the native NFET 206 turns on. When the native NFET 206 is turned on, the intermediate voltage begins to increase. Further, the PFET 204 begins to conduct such that the output voltage at output terminal 254 increases similar to the intermediate voltage until both the intermediate voltage and the output voltage are substantially equivalent to the second input voltage (e.g., 3.6 volts).

Accordingly the result is that as the input signal at terminal 250 transitions from a logic low (e.g. 0 volts) to a logic high (e.g. 1.8 volts), the output terminal 254 transitions from a logic high to logic low (e.g. 0 volts). Likewise, as the input signal at terminal 250 transition from a logic high (e.g. 1.8 volts) to a logic low (e.g. 0 volts), the output terminal 254 transitions from a logic low to logic high that is determined by the voltage on the second input terminal 252, namely high voltage VH described above (e.g. 3.6 volts).

### Other Exemplary Embodiments

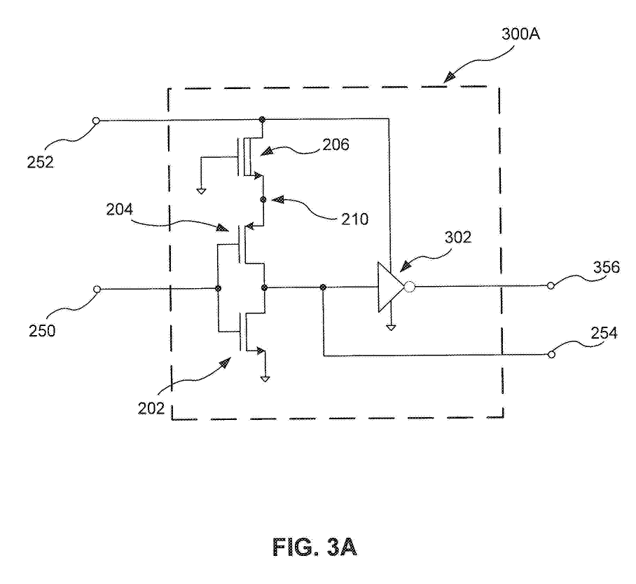

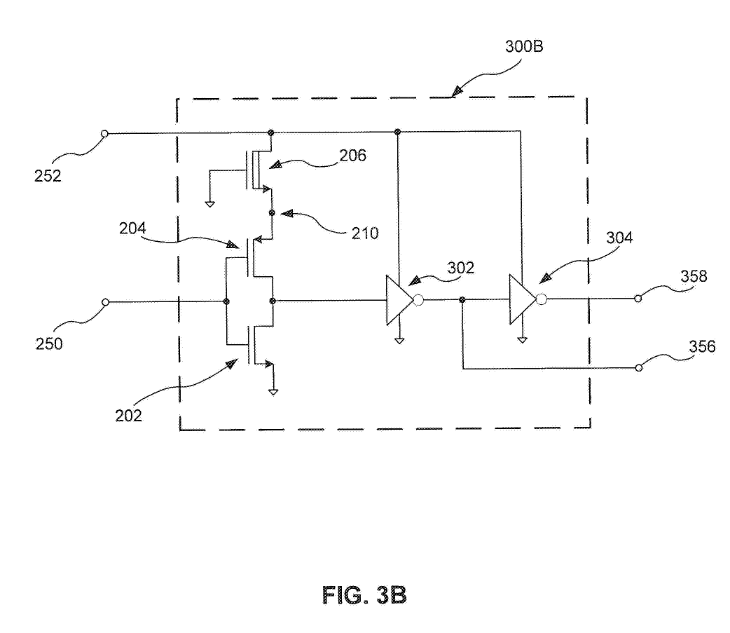

FIG. 3A illustrates a level shifter circuit 300A, in accordance with an embodiment of the present disclosure. As shown by FIG. 3A, the level shifter circuit 300A includes the NFET 202, the PFET 204, and the native NFET 206 arranged in a similar manner to the level shifter circuit 200. The level shifter circuit 300A also includes an inverter 302 configured to output an inverted signal of the output signal on output terminal 254. The inverter 302 includes an input terminal, a Vdd terminal (e.g. bias supply terminal), a Vss terminal, and an output terminal 356. The input terminal of the inverter 302 connects to the output terminal 254, and the output terminal 356 is provided as an additional output of the level shifter circuit 300A. The Vdd terminal of the inverter 302 connects to the second input voltage such that the inverter 302 outputs a signal substantially equally to the second input voltage (e.g., 3.6 volts) when the first input signal is at the highest voltage (e.g., 1.8 volts). The Vss terminal of the inverter 302 connects to ground such that the output of the inverter 302 is 0 volts when the first input signal is at the lowest voltage (e.g., 0 volts). The above-described arrangement of the level shifter circuit 300A provides a complementary output level shifter so that the output signal provides a level shifted output of the input signal at output terminal 356 and a logical compliment thereof at output terminal 254. The result is that as the input signal at terminal 250 transitions from a logic low (e.g. 0 volts) to a logic high (e.g. 1.8 volts), the output terminal 254 transitions from a logic high to logic low (e.g. 0 volts) and the output terminal 356 transitions to a logic high that is determined by the voltage on the second input terminal 252, namely high voltage VH described above (e.g. 3.6 volts). Likewise, as the input signal at terminal 250 transition from a logic high (e.g. 1.8 volts) to a logic low (e.g. 0 volts), the output terminal 254 transitions to from a logic low to a logic high that is determined by the voltage on the second input terminal 252, namely high voltage VH described above (e.g. 3.6 volts) and the output terminal 356 transitions to a logic low (e.g. 0 volts).

FIG. 3B illustrates a level shifter circuit 300B, in accordance with an embodiment of the present disclosure. As shown by FIG. 3B, the level shifter circuit 300B includes the NFET 202, the PFET 204, the native NFET 206, and the inverter 302 arranged similar to the inverting level shifter circuit 300A. The level shifter circuit 300B also includes an inverter 304 configured to output an inverted signal of the output of inverter 302 on the output terminal 356. The inverter 304 includes an input terminal, a Vdd terminal, a Vss terminal, and an output terminal 358. The input terminal of the inverter 304 connects to the output terminal 356 of the inverter 302, and the output terminal 358 of the inverter 304 is provided as another output of the level shifter circuit 300B. The Vdd terminal of the inverter 304 connects to the second input voltage such that the output signal of the inverter 304 is substantially equally to the second input voltage (e.g., 3.6 volts) when the first input signal is at the lowest voltage (e.g., 0 volts). The Vss terminal of the inverter 304 connects to ground such that the output of the inverter 304 is substantially 0 volts when the first input signal is at the highest voltage (e.g., 1.8 volts).

The level shifter circuit 300B of FIG. 3B provides equalized complementary outputs because the inverters 302 and 304 create sharper edges for both the output terminals 356 and 358.

### Device Using Level Shifter as a Reset

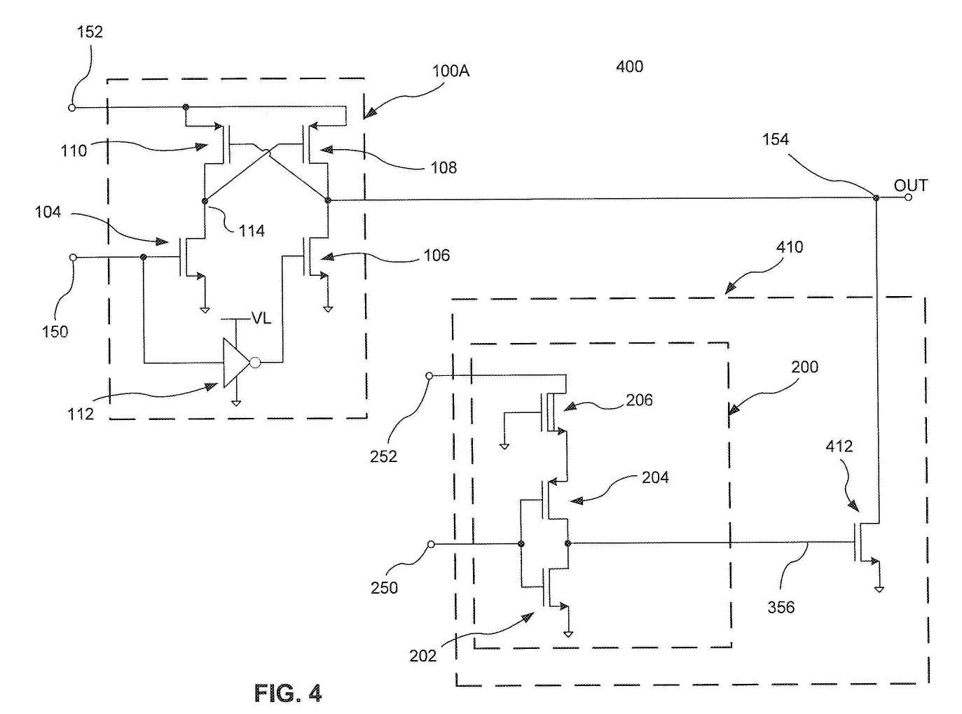

FIG. 4 illustrates a device 400 using a level shifter, in accordance with an embodiment of the present disclosure, as a reset circuit. As shown by FIG. 4, the device 400 includes the level shifter circuit 100A and a reset circuit 410. As previously stated, the level shifter circuit 100A is a cross-coupled level shifter, which allows the output of the inverter 112 to go to an uncontrolled voltage of either the low voltage VL or ground when the input signal on the input terminal 150 is lost, becomes disconnected, or floats. Further, the output signal can remain at the uncontrolled voltage even if the input signal goes to 0 volts. The uncontrolled voltage can be potentially problematic to the device 400 especially when the device is a low powered device.

To correct these issues of the level shifter circuit 100A, a reset circuit 410 can be connected to the output terminal 154 of the level shifter circuit 100A, as shown. The reset circuit 410 includes the level shifter circuit 200, described above, and a pull-down transistor 412. The level shifter circuit 200 receives a reset signal on the input terminal 250 that controls the reset of level shifter circuit 100A. In other words, the reset signal is set to a logic low when reset of level shifter circuit 100A is desired. The level shifter circuit 200 functions, as previously described, such that when the reset signal is at a logic low voltage (logic 0), the output of the level shifter 200 on the output terminal 356 is equal to the second input signal on the second input terminal 252, e.g. the high voltage VH. As an example, if the second input signal on the second input terminal 252 is 3.6 volts, the output signal on the output terminal 356 is 3.6 volts when the reset signal on the input terminal 250 is 1.8 volts.

The pull-down transistor 412 includes a gate connected to the output terminal 356 of the level shifter circuit 200, a source connected to ground, and a drain connected to the output terminal 154 of the level shifter circuit 100A. The pull-down transistor 412 performs a reset operation to connect the output terminal 154 to ground when the output of the level shifter circuit 200 is equal to the second input voltage (e.g., 3.6 volts). By using the reset circuit 410, the device 400 can be set to a known state even when the input signal is lost on the input terminal 150 of the level shifter circuit 100A.

In other embodiments, the reset circuit 410 may include multiple pull-down transistors 412 such that multiple level shifter circuits 100A can use the benefits of the reset circuit 410. In detail, the output terminal 356 of the level shifter circuit 200 can be connected, as described above, to multiple pull-down transistors 412, where each of the multiple pull-down transistors 412 is connected to an output terminal of a respective level shifter circuit 100A.

As will be understood by those skilled in the arts, the device 400 is not limited to the level shifter circuit 100A, as described above, and can be any level shifter circuit which fails to retain a controlled output voltage when an input signal is lost. Further, those skilled in the arts will understand that, based on different configurations of the device 400, the reset signal on the input terminal 250 may be the same signal or a different signal than the input signal on the input terminal 150 in order to assure that the output terminal 154 is at a known state, and the signal on the high voltage terminal 152 may be the same or a different signal than the signal on the second input terminal 252.

Further, throughout this specification, the specific voltage levels described herein (e.g. 1.8 v and 3.6 v) are provided for example purposes only, and are not meant to be limiting of the disclosure. Other low and high voltage levels can used without deviating from the scope and spirit of the disclosure, as will be understood by those skilled in arts based on discussion provided herein.

The exemplary embodiments described herein are provided for illustrative purposes, and are not limiting. Other exemplary embodiments are possible, and modifications may be made to the exemplary embodiments within the spirit and scope of the disclosure.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

It will be apparent to those skilled in the relevant art(s) that various changes in form and detail can be made therein without departing from the spirit and scope of the disclosure. Thus the disclosure should not be limited by any of the above-described exemplary embodiments. Further, the claims should be defined only in accordance with their recitations and their equivalents.

1. A level shifter circuit, comprising:
an N-type field-effect transistor (NFET) including a gate connected to a first input terminal, a source connected to ground, and a drain connected to a first output terminal;
a P-type field-effect transistor (PFET) including a gate connected to the first input terminal, a source, and a drain connected to the first output terminal;
a native NFET including a gate connected to ground, a source connected to the source of the PFET, and a drain connected to a second input terminal;
a first inverter including an input connected to the first output terminal; and
wherein the level shifter circuit is configured to output a respective level shifted signal on both the first output terminal and an output of the first inverter.

2. The level shifter circuit of claim 1, wherein the first input terminal receives a first input signal having a predetermined voltage range.

3. The level shifter circuit of claim 2, wherein the second input terminal receives a second input signal having a predetermined voltage that is greater than a highest voltage of the predetermined voltage range of the first input signal.

4. (canceled)

5. (canceled)

6. The level shifter circuit of claim 1, further comprising a second inverter including an input connected to the output of the first inverter.

7. The level shifter circuit of claim 6, wherein the level shifter circuit is configured to output signals on the output of the first inverter and an output of the second inverter.

8-14. (canceled)

15. A level shifter circuit, comprising:
a field effect transistor (FET) inverter including a first input terminal, an intermediate terminal, a ground connection, and a first output terminal; and
a native FET connected between the intermediate terminal of the FET inverter and a high voltage terminal, wherein the native FET is configured to reduce a current flow between the high voltage terminal and the FET inverter; and
a second inverter including a second input terminal connected to the first output terminal, a supply terminal connected to the high voltage terminal, a ground connection, and a second output terminal,
wherein the level shifter circuit is configured to output a respective level shifted signal on both the first output terminal and the second output terminal.

16. The level shifter circuit of claim 15, wherein the native FET comprises a gate connected to ground, a source connected to the supply terminal of the FET inverter, and a drain connected to the high voltage terminal.

17. (canceled)

18. The level shifter circuit of claim 15, further comprising a third inverter including a third input terminal connected to the second output terminal, a supply terminal connected to the high voltage terminal, a ground connection, and a third output terminal.

19. The level shifter circuit of claim 15, wherein the first input terminal receives a first input signal having a predetermined voltage range.

20. The level shifter circuit of claim 19, wherein the high voltage terminal receives a second input signal having a predetermined voltage that is greater than a highest voltage of the predetermined voltage range of the first input signal.

21. An electronic device, comprising:
a level shifter configured to vary an output signal on a first output terminal based on a first input signal on a first input terminal and a second input signal on a high voltage terminal, the level shifter comprising:
an inverter; and
a native field-effect transistor (FET) configured to reduce a current flow between the high voltage terminal and the inverter; and
a second inverter including a second input terminal connected to the first output terminal, a supply terminal connected to the second input terminal, a ground connection, and a second output terminal,
wherein the electronic device is configured to output a respective level shifted signal on both the first output terminal and the second output terminal.

22. The electronic device of claim 21, wherein the native FET is further configured to be in an “on” state or a subthreshold region.

23. The electronic device of claim 22, wherein the first input signal has a predetermined voltage range, and the second input signal has a voltage that is greater than a highest voltage of the predetermined voltage range of the first input signal.

24. The electronic device of claim 23, wherein the native FET comprises a gate connected to ground, a source connected to the inverter, and a drain connected to the second input terminal.

25. The electronic device of claim 24, wherein the inverter includes an N-type FET (NFET) and a P-type FET (PFET).

26. The electronic device of claim 25, wherein the NFET comprises a gate connected to the first input terminal, a source connected to ground, and a drain connected to the first output terminal.

27. The electronic device of claim 26, wherein the PFET comprises a gate connected to the first input terminal, a source connected to ground, and a drain connected to the first output terminal.
